(19) United States
(12) Patent Application Publication
(10) Pub. No.: US 2014/0043768 A1
(43) Pub. Date: Feb. 13, 2014

(54) PACKAGE RETENTION FRAME

(71) Applicants: Mahesh Hardikar, San Jose, CA (US); Stephen F. Heng, Los Gatos, CA (US)

(72) Inventors: Mahesh Hardikar, San Jose, CA (US); Stephen F. Heng, Los Gatos, CA (US)

(73) Assignee: Advanced Micro Devices, Inc., Sunnyvale, CA (US)

(21) Appl. No.: 13/570,455

(22) Filed: Aug. 9, 2012

(51) Int. Cl. H05K 7/02; H01R 43/00; H05K 7/20

(52) U.S. Cl. 361/718; 361/807; 29/825

(57) ABSTRACT

The present invention provides embodiments of a package retention frame. One embodiment of the package retention frame is configured for deployment adjacent a top surface of an integrated circuit package. A grid of contacts is on a bottom surface of the integrated circuit package. The package retention frame when deployed substantially maintains alignment of the grid of contacts with a grid of pins in a socket. An outer boundary of the package retention frame is substantially encompassed by an outer boundary of the socket.

### BACKGROUND

This application relates generally to integrated circuit systems, and, more particularly, to a package retention frame for use in an integrated circuit system.

Integrated circuits are typically packaged and then mounted on the surface of a printed circuit board. For example, the integrated circuit packaging can include a set of pins distributed around the perimeter of the package that provide a physical, electromagnetic, or communicative coupling between the integrated circuit within the package and other elements that may be mounted on the printed circuit board. For another example, an array of pins may be arranged on the underside of the integrated circuit package to form a pin grid array. Packages that include a pin grid array may then be mounted on a printed circuit board using through-hole technology or by inserting the pin grid array into a socket. The socket includes an opening corresponding to each pin in the pin grid array. The socket may also include retention clips that supply a force that must be overcome to mate the package to the socket. The applied force may be referred to as a socket actuation force.

Alternatively, a land grid array (LGA) may be formed on the underside of the integrated circuit package and used to couple the integrated circuit package to the printed circuit board. A land grid array differs from a pin grid array because the pins for the land grid array are deployed in the socket. The integrated circuit package may therefore include pads such as gold-plated copper pads that make physical or electromagnetic contact with the pins in the socket when the package is mated with the socket. A conventional LGA package includes a socket actuation mechanism to provide the socket actuation force that couples the package to the socket. A typical socket actuation mechanism includes a metallic frame that is held in place by a clamshell-type clamp. A heat sink is typically placed in thermal contact with the package after it has been locked in place by the socket actuation mechanism. The socket actuation mechanism consumes significant area on the printed circuit board and adds significant height to the LGA package.

### SUMMARY OF EMBODIMENTS

The disclosed subject matter is directed to addressing the effects of one or more of the problems set forth above. The following presents a simplified summary of the disclosed subject matter in order to provide a basic understanding of some aspects of the disclosed subject matter. This summary is not an exhaustive overview of the disclosed subject matter. It is not intended to identify key or critical elements of the disclosed subject matter or to delineate the scope of the disclosed subject matter. Its sole purpose is to present some concepts in a simplified form as a prelude to the more detailed description that is discussed later.

Embodiments of the package retention frame described herein may replace conventional socket actuation mechanisms such as clamshell-type clamps that are used to mate an integrated circuit package to a socket. The package retention frame maintains alignment of the contacts on the underside of an integrated circuit package and the pins in a socket. Although the package retention frame may supply a portion of the socket actuation force in some embodiments, alignment of the pins and the contacts may be maintained regardless of the amount of force applied by the package retention frame. The outer boundary of the package retention frame corresponds to the outer boundary of the socket and so the package retention frame consumes little or no extra area beyond the outer boundary of the socket.

In one embodiment, embodiments of a package retention frame are provided. One embodiment of the package retention frame is configured for deployment adjacent a top surface of an integrated circuit package. A grid of contacts is on a bottom surface of the integrated circuit package. The package retention frame when deployed substantially maintains alignment of the grid of contacts with a grid of pins in a socket. An outer boundary of the package retention frame is substantially encompassed by an outer boundary of the socket.

In another embodiment, embodiments of an apparatus are provided. One embodiment of the apparatus includes a socket including a grid of pins, an integrated circuit package that includes a grid of contacts on a bottom surface of the integrated circuit package, and a package retention frame adjacent a top surface of the integrated circuit package. An outer boundary of the package retention frame is substantially encompassed by an outer boundary of the socket. The package retention frame substantially maintains alignment of the grid of contacts with the grid of pins.

In yet another embodiment, embodiments of a method are provided. One embodiment of the method includes positioning a package retention frame adjacent a top surface of an integrated circuit package that includes a grid of contacts on a bottom surface of the integrated circuit package. The package retention frame substantially maintains alignment of the grid of contacts with a grid of pins in a socket. An outer boundary of the package retention frame is substantially encompassed by an outer boundary of the socket.

In a further embodiment, an integrated circuit package is provided. One embodiment of the integrated circuit package includes a grid of contacts on a bottom surface of the integrated circuit package and an package retention frame embedded adjacent a top surface of the integrated circuit package. The package retention frame when deployed substantially maintains alignment of the grid of contacts with a grid of pins in a socket. An outer boundary of the package retention frame when deployed is substantially encompassed by an outer boundary of the socket.

### BRIEF DESCRIPTION OF THE DRAWINGS

The disclosed subject matter may be understood by reference to the following description taken in conjunction with the accompanying drawings, in which like reference numerals identify like elements, and in which:

FIG. 1 conceptually illustrates a top view of a first embodiment of a package retention frame that is deployed within a socket housing;

FIGS. 2A and 2B conceptually illustrate top views and cross-sectional views of a package retention frame that is deployed within a socket;

FIG. 2C shows a perspective view of one exemplary embodiment of the package retention frame installed in the socket;

FIG. 2D shows an exploded view of one exemplary embodiment of the assembly including the package retention frame, the socket, and the integrated circuit;

FIG. 3 conceptually illustrates a top view of a second exemplary embodiment of a package retention frame;

FIGS. 4A and 4B conceptually illustrate top views and cross-sectional views of a package retention frame that is deployed within and partially over a socket; and

FIG. 4C shows a perspective view of one exemplary embodiment of the package retention frame installed in and partially over the socket.

While the disclosed subject matter may be modified and may take alternative forms, specific embodiments thereof have been shown by way of example in the drawings and are herein described in detail. It should be understood, however, that the description herein of specific embodiments is not intended to limit the disclosed subject matter to the particular forms disclosed, but on the contrary, the intention is to cover all modifications, equivalents, and alternatives falling within the scope of the appended claims.

### DETAILED DESCRIPTION OF SPECIFIC EMBODIMENTS

Illustrative embodiments are described below. In the interest of clarity, not all features of an actual implementation are described in this specification. It will of course be appreciated that in the development of any such actual embodiment, numerous implementation-specific decisions should be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure. The description and drawings merely illustrate the principles of the claimed subject matter. It should thus be appreciated that those skilled in the art may be able to devise various arrangements that, although not explicitly described or shown herein, embody the principles described herein and may be included within the scope of the claimed subject matter. Furthermore, all examples recited herein are principally intended to be for pedagogical purposes to aid the reader in understanding the principles of the claimed subject matter and the concepts contributed by the inventor(s) to furthering the art, and are to be construed as being without limitation to such specifically recited examples and conditions.

The disclosed subject matter is described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the disclosed subject matter. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition is expressly set forth in the specification in a definitional manner that directly and unequivocally provides the special definition for the term or phrase. Additionally, the term, “or,” as used herein, refers to a non-exclusive “or,” unless otherwise indicated (e.g., “or else” or “or in the alternative”). Also, the various embodiments described herein are not necessarily mutually exclusive, as some embodiments can be combined with one or more other embodiments to form new embodiments.

As discussed herein, a land grid array (LGA) is a packaging technology that uses a grid of contacts on the underside of an integrated circuit package to connect the integrated circuit package to an LGA socket on a printed circuit board. Pins are located on the LGA socket and not on the integrated circuit package. A conventional LGA package includes a socket actuation mechanism to provide the actuation force that couples the package to the socket. A conventional socket actuation mechanism includes a metallic frame that is held in place by a clamshell-type clamp. A heat sink is typically placed in thermal contact with the package after it has been locked in place by the socket actuation mechanism. The socket actuation mechanism consumes significant area on the printed circuit board. For example, a typical clamshell design may occupy an area that is 50 to 100% larger than the integrated circuit package. Furthermore, the socket actuation mechanism adds significant height to the LGA package. For example, the height of a typical printed circuit board is about 1 mm. The LGA package may add about 2 mm and the clamshell-type socket actuation mechanism adds an additional 5 mm of height.

Embodiments of the package retention frame described herein may be used instead of the clamshell-type socket actuation mechanism. Embodiments of the package retention frame can hold the integrated circuit substantially in alignment with the LGA socket even when no loading mechanism has been deployed or actuated. Thus, embodiments of the package retention frame can securely hold an LGA package within an LGA socket in the absence of a socket actuation mechanism. The outer boundary of the package retention frame (e.g., a boundary in the plane of the surface of the die) may be substantially equal to or encompassed by the boundary of the LGA socket. The retention frame may be attached using clips around the boundary of the LGA socket. In some embodiments, the package retention frame may supply sufficient force to mate the package in the socket, e.g., for low pin count packages. In other embodiments, an additional socket actuation force may be applied to mate the package in the socket. The socket actuation force can be applied by deploying a heat sink adjacent to the package retention frame. In various embodiments, a top surface of the package retention frame may be flush with or below a top surface of the die. The heat sink may therefore contact the integrated circuit, the package retention frame, or both to provide the load that mates the package with the socket. Regardless of whether the package retention frame supplies the load that mates the package and the socket, the package retention frame can maintain alignment of the integrated circuit and the LGA socket during deployment or removal of the heat sink.

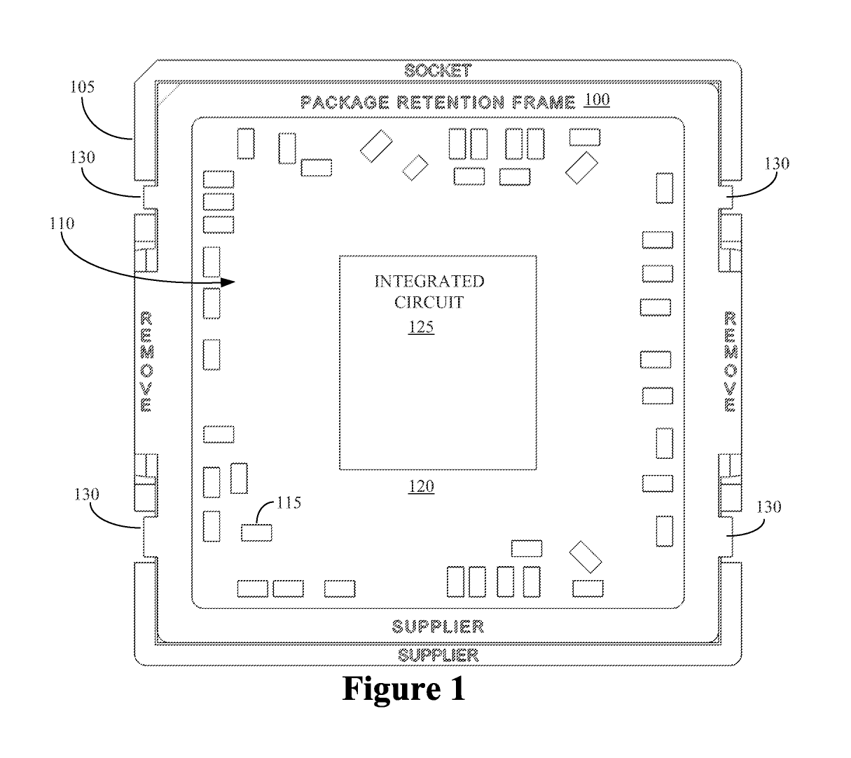

FIG. 1 conceptually illustrates a top view of a first embodiment of a package retention frame 100 that is deployed within a socket housing 105. In the illustrated embodiment, the package retention frame 100 maintains alignment of pads of an integrated circuit package 110 with pins (not shown in FIG. 1) in the socket housing 105. The integrated circuit package 110 includes elements 115 such as resistors, capacitors, inductors, or other electromagnetic elements that are mounted on a substrate 120. The integrated circuit package 110 also includes an integrated circuit 125 that is mounted on the substrate 120. Lines or traces may be formed in or on the substrate 120 to physically, electromagnetically, or communicatively couple the elements 115, the integrated circuit 125, or the pads of the integrated circuit package 110. In one embodiment, the integrated circuit 125 may include a central processing unit (CPU). Alternatively, the integrated circuit 125 may include a graphics processing unit (GPU), an accelerated processing unit (APU), an application-specific integrated circuit (ASIC), a field programmable gate array (FPGA), or other circuit.

The dimensions of the package retention frame 100 are selected so that the perimeter of the package retention frame 100 is substantially encompassed by the perimeter of the socket housing 105. As used herein, the term “substantially encompassed” should be understood to mean that boundaries of the package retention frame 100 in the plane defined by the horizontal dimensions of the socket housing 105 (e.g., the plane of FIG. 1) are for the most part the same as or within the boundaries of the socket housing 105. Persons of ordinary skill in the art having benefit of the present disclosure should appreciate that some portions of the package retention frame 100 may extend beyond some portions of the socket 105 even though the package retention frame 100 is substantially encompassed by the socket 105. For example, tabs (labeled REMOVE in FIG. 1) of the package retention frame 100 may extend over portions of the socket 105 even though the tabs are substantially encompassed by the socket 105.

The package retention frame 100 may be physically coupled or attached to the socket 105 using one or more clips 130. As discussed herein, the clips 130 are distributed around the perimeter of the package retention frame 100 and may be used to attach the package retention frame 100 to corresponding slots in the socket 105. However, persons of ordinary skill in the art having benefit of the present disclosure should appreciate that alternative embodiments of the package retention frame 100 may use other structures such as fasteners, latches, and the like to attach the package retention frame 100 to the socket 105, the integrated circuit package 110, or an underlying printed circuit board so that the package retention frame 100 maintains alignment of the integrated circuit package 110 with the socket 105.

In one embodiment, attaching the package retention frame 100 using the clips 130 may provide a sufficient socket actuation force to mate the pins in the socket 105 with the pads on the integrated circuit package 110. For example, low pin count integrated circuit packages may require a smaller socket actuation force, which can be provided by attaching the package retention frame 100 using the clips 130. Thus, the clips 130 may provide the socket actuation force for integrated circuit packages that have a number of pins that is below a threshold value that corresponds to low pin count integrated circuits. Embodiments of the package retention frame 100 may be formed out of plastic, metal, or other materials. For example, a plastic package retention frame 100 may advantageously be an insulator and may be relatively lightweight and easy to fabricate. For another example, a metallic package retention frame 100 may advantageously be conducting and may be able to supply a larger socket actuation force without deforming or breaking. In alternative embodiments, a ball grid array (BGA) may be used on the integrated circuit package 110 instead of pads and in the alternative embodiment, the package retention frame 100 can provide the socket actuation force to mate the pins (not shown in FIG. 1) in the socket housing 105 to the ball grid array on the integrated circuit package 110.

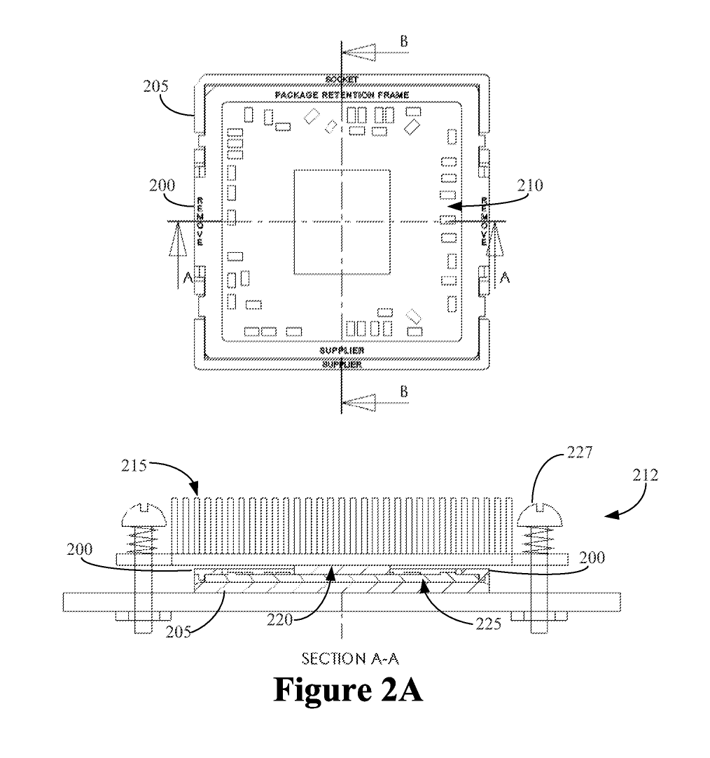

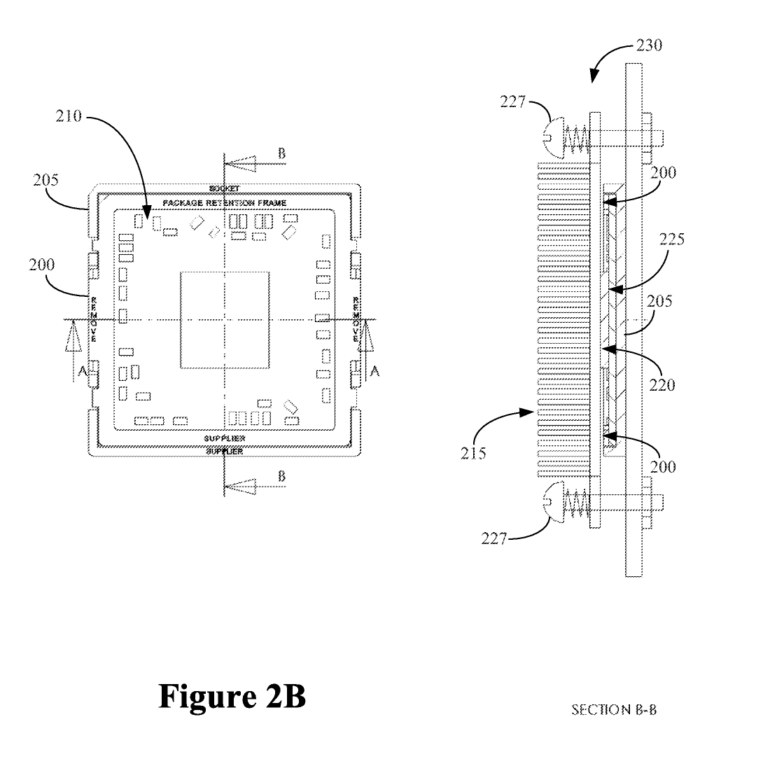

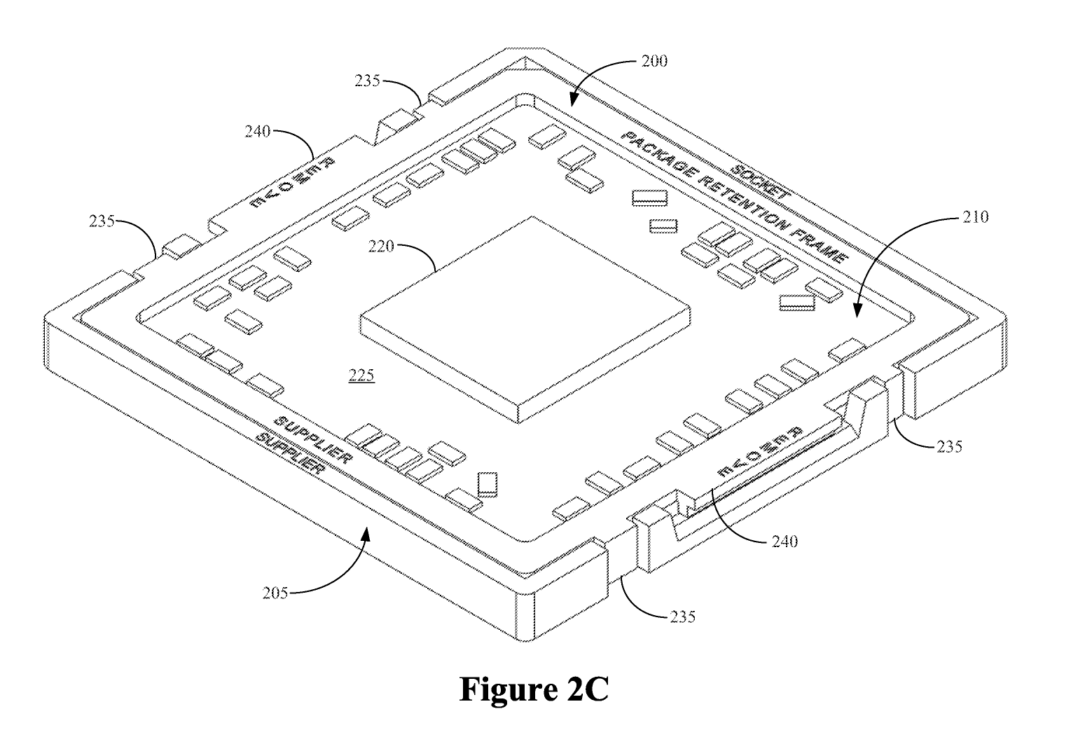

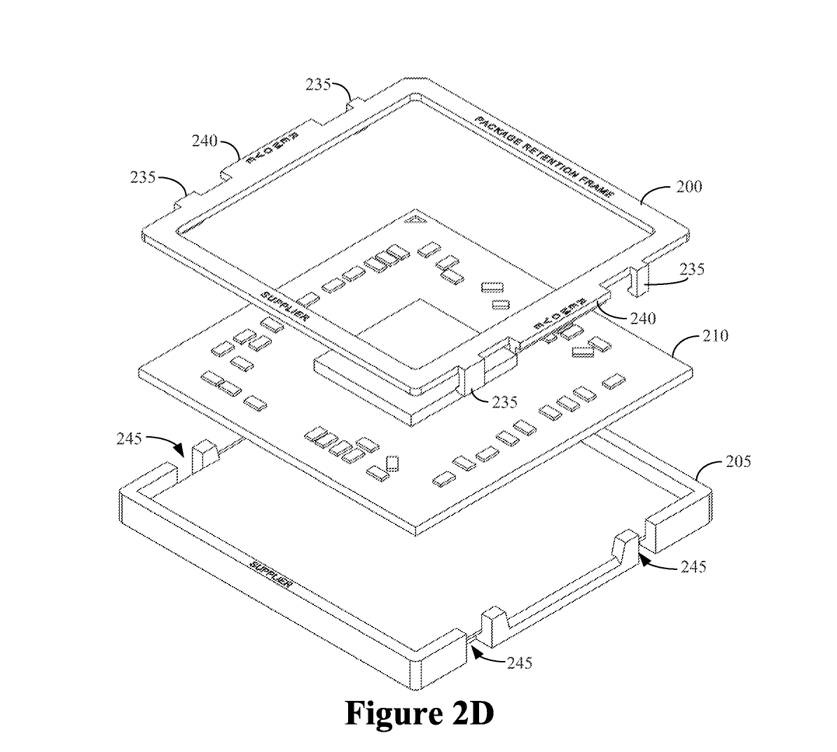

FIGS. 2A and 2B conceptually illustrate top views and cross-sectional views of a package retention frame 200 that is deployed within a socket 205. The package retention frame 200 maintains alignment of the socket 205 and an integrated circuit package 210. FIG. 2A also depicts a cross-sectional view 212 along the line A-A. The cross-sectional view 212 includes a heat sink 215 that is deployed over the package retention frame 200, the socket 205, and the integrated circuit package 210. Alternatively, other thermal assemblies or devices may be deployed over the package retention frame 200, the socket 205, or the integrated circuit package 210. The cross-sectional view 212 also shows the integrated circuit 220 that is attached to the substrate 225. In the illustrated embodiment, the package retention frame 200 maintains alignment of the pads (not shown) on the bottom surface of the substrate 225 with the pins (not shown) on the top surface of the socket 205. Deployment of the heat sink 215 provides a socket actuation force (e.g., a downward force in FIG. 2A) that mates the pads (not shown) on the bottom surface of the substrate 225 with the pins (not shown) on the top surface of the socket 205 so that a physical, electromagnetic, or communicative connection is formed between the pins and the pads. For example, screws or bolts 227 may be used to hold the heat sink 215 in place and provide the socket actuation force. In the illustrated embodiment, a top surface of the package retention frame 200 is below a top surface of the integrated circuit 220 so that the heat sink 215 contacts the top surface of the integrated circuit 220 but does not contact the top surface of the package retention frame 200.

FIG. 2B depicts a cross-sectional view 230 along the line B-B. The cross-sectional view 230 shows the heat sink 215 deployed over the package retention frame 200, the socket 205, and the integrated circuit package 210. As discussed with regard to FIG. 2A, the package retention frame 200 maintains alignment of the pads (not shown) on the bottom surface of the substrate 225 with the pins (not shown) on the top surface of the socket 205. Deployment of the heat sink 215 provides the socket actuation force (e.g., a left-to-right force provided by the bolts 227 in FIG. 2B) that mates the pads with the pins so that a physical, electromagnetic, or communicative connection is formed between the pins and the pads. The top surface of the package retention frame 200 is below the top surface of the integrated circuit 220 so that the heat sink 215 contacts the top surface of the integrated circuit 220 but does not contact the top surface of the package retention frame 200.

FIG. 2C shows a perspective view of one exemplary embodiment of the package retention frame 200 installed in the socket 205. The perspective view shows clips 235 that are used to fasten the package retention frame 200 to the socket 205. The perspective view also shows tabs 240 that may be used to remove the package retention frame 200 from the socket 205. As discussed herein, the package retention frame 200 maintains alignment of the socket 205 and the integrated circuit package 210 when the clips 235 are attached to the socket 205. The package retention frame 200 may also provide a portion of a socket actuation force when the clips 235 are attached to the socket 205.

FIG. 2D shows an exploded view of one exemplary embodiment of the assembly including the package retention frame 200, the socket 205, and the integrated circuit 210. The illustrated embodiment shows the clips 235 disconnected from the socket 205. The illustrated embodiment also shows the slots or latches 245 that are formed in the socket 205 to provide attachment and alignment points for the clips 235. The slots 245 provide recesses in the housing wall of the socket 205 so that the clips 235 are substantially encompassed by the outer boundary of the socket 205 when the package retention frame 200 is installed or attached to the socket 205. In the illustrated embodiment, the package retention frame 200, the sockets 205, and the integrated circuit 210 are depicted as three separate elements that may be independently manufactured or sold. However, combinations of the package retention frame 200, the sockets 205, and the integrated circuit 210 may be combined. For example, a vendor may produce an integrated circuit package that includes the integrated circuit 210 and a package retention frame 200 that is embedded, manufactured, or attached in or on the package.

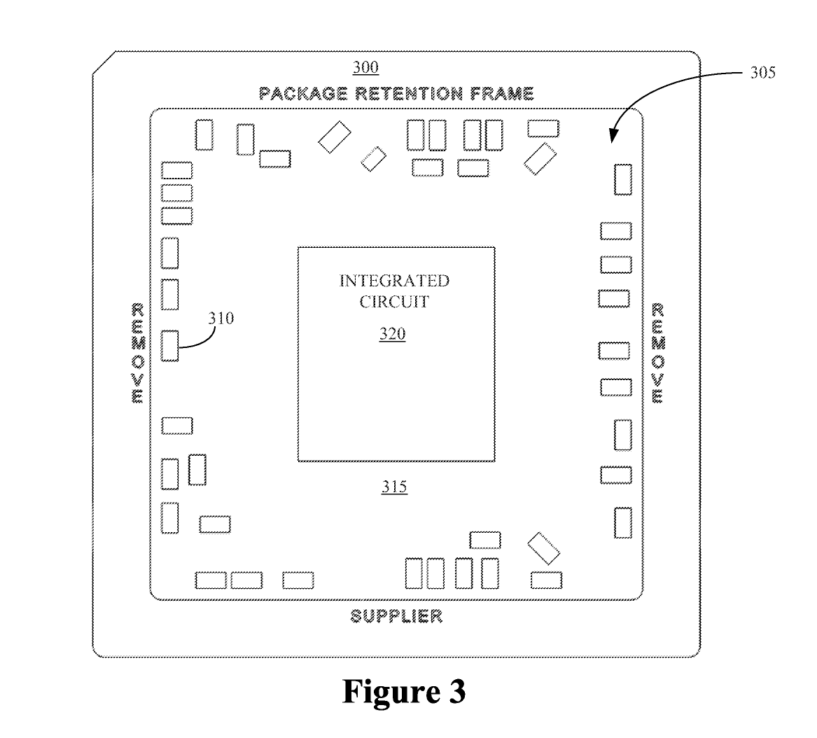

FIG. 3 conceptually illustrates a top view of a second exemplary embodiment of a package retention frame 300. In the illustrated embodiment, the package retention frame 300 includes a flange that extends over a socket housing that is configured to receive an integrated circuit package 305. Nevertheless, as discussed herein, the perimeter of the package retention frame 300 is substantially the same or encompassed by the perimeter of the socket housing. The package retention frame 300 can be deployed to maintain alignment of pads of the integrated circuit package 305 with pins (not shown in FIG. 3) in the socket housing. The integrated circuit package 305 includes elements 310 such as resistors, capacitors, inductors, or other electromagnetic elements that are mounted on a substrate 315. The integrated circuit package 305 also includes an integrated circuit 320 that is mounted on the substrate 315. Lines or traces may be formed in or on the substrate 315 to physically, electromagnetically, or communicatively couple the elements 310, the integrated circuit 320, or the pads of the integrated circuit package 305. As discussed herein, embodiments of the integrated circuit 320 may include a central processing unit (CPU), a graphics processing unit (GPU), an accelerated processing unit (APU), an application-specific integrated circuit (ASIC), a field programmable gate array (FPGA), or other circuit.

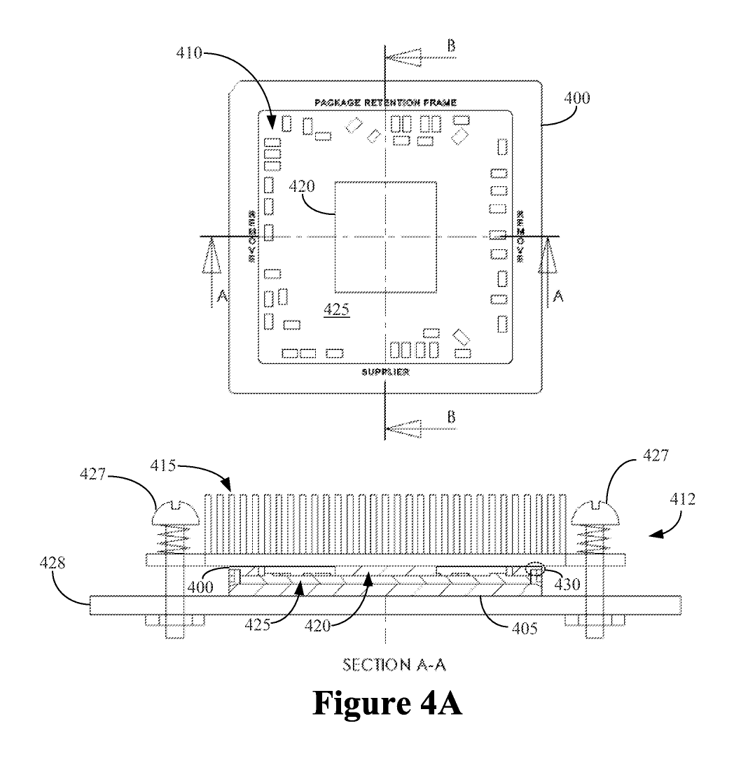

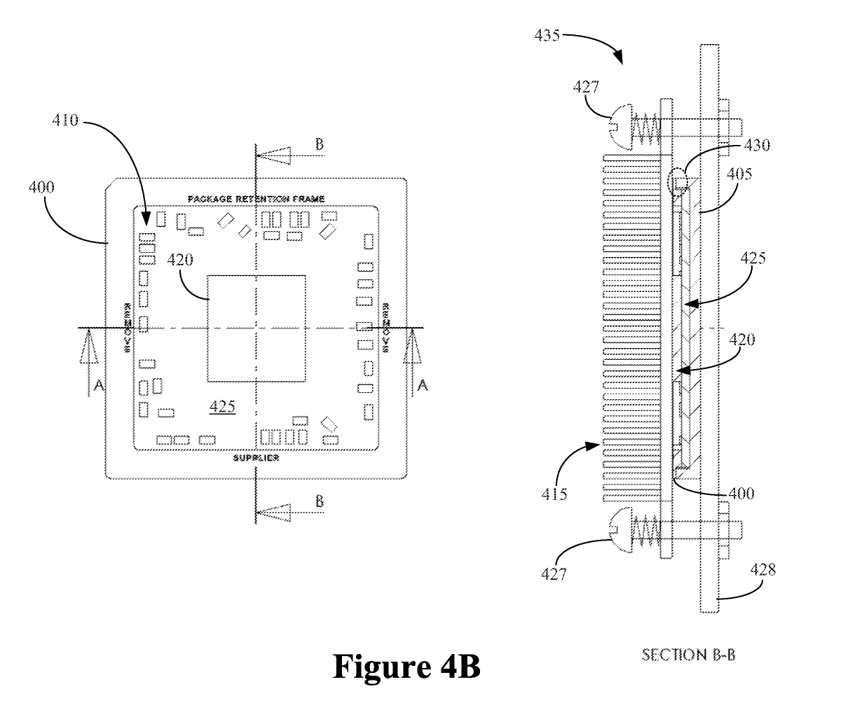

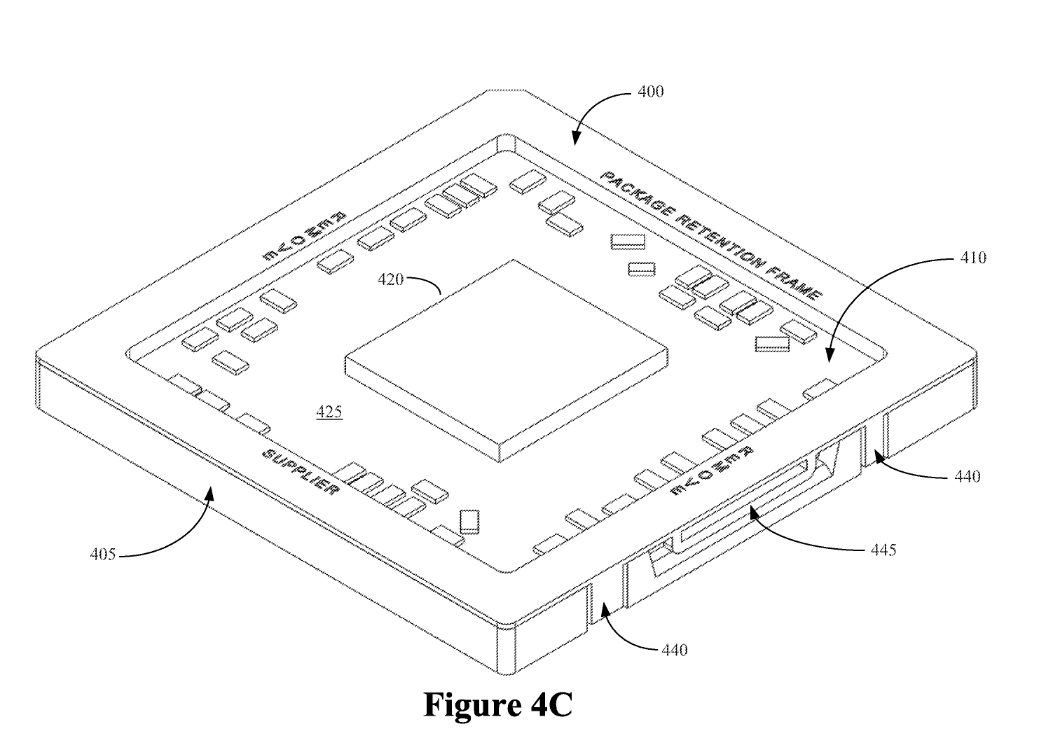

FIGS. 4A and 4B conceptually illustrate top views and cross-sectional views of a package retention frame 400 that is deployed within and partially over a socket 405. The package retention frame 400 maintains alignment of the socket 405 and an integrated circuit package 410. FIG. 4A also depicts a cross-sectional view 412 along the line A-A. The cross-sectional view 412 includes a heat sink 415 that is deployed over the package retention frame 400, the socket 405, and the integrated circuit package 410. The cross-sectional view 412 also shows the integrated circuit 420 that is attached to the substrate 425. In the illustrated embodiment, the package retention frame 400 maintains alignment of the pads (not shown) on the bottom surface of the substrate 425 with the pins (not shown) on the top surface of the socket 405. The cross-sectional view 412 also shows the flange 430 that extends over a housing wall of the socket 405. In the illustrated embodiment, the flange 430 does not extend beyond the outer boundary of the socket 405.

Deployment of the heat sink 415 provides a socket actuation force (e.g., a downward force in FIG. 4A) that mates the pads (not shown) on the bottom surface of the substrate 425 with the pins (not shown) on the top surface of the socket 405 so that a physical, electromagnetic, or communicative connection is formed between the pins and the pads. For example, screws or bolts 427 may be used to fasten the heat sink 415 to a chip 428 and provide the socket actuation force. In the illustrated embodiment, a top surface of the package retention frame 400 is flush with a top surface of the integrated circuit 420 so that the heat sink 415 contacts the top surface of the integrated circuit 420 and the top surface of the package retention frame 400. The socket actuation force provided by the heat sink 415 is therefore distributed over the top surfaces of both the integrated circuit 420 and the package retention frame 400.

FIG. 4B depicts a cross-sectional view 435 along the line B-B. The cross-sectional view 435 shows the heat sink 415 deployed over the package retention frame 400, the socket 405, and the integrated circuit package 410. As discussed with regard to FIG. 4A, the package retention frame 400 maintains alignment of the pads (not shown) on the bottom surface of the substrate 425 with the pins (not shown) on the top surface of the socket 405. Deployment of the heat sink 415 provides the socket actuation force (e.g., a left-to-right force provided by the bolts 427 in FIG. 4B) that mates the pads with the pins so that a physical, electromagnetic, or communicative connection is formed between the pins and the pads. The top surface of the package retention frame 400 is flush with the top surface of the integrated circuit 420 so that the heat sink 415 contacts the top surface of the integrated circuit 420 and the top surface of the package retention frame 400.

FIG. 4C shows a perspective view of one exemplary embodiment of the package retention frame 400 installed in and partially over the socket 405. The perspective view shows clips 440 that are used to fasten the package retention frame 400 to the socket 405. As discussed herein, the package retention frame 400 maintains alignment of the socket 405 and the integrated circuit package 410 when the clips 440 are attached to the socket 405. The package retention frame 400 may also provide a portion of a socket actuation force when the clips 440 are attached to the socket 405. Tabs 445 may be used to remove the package retention frame 400 from the socket 405.

Embodiments of the package retention frames described herein may have a number of advantages over the conventional clamshell type fastener. The package retention frames may insure that the integrated circuit package (such as a land grid array package) does not dislodge from the corresponding socket when cooling hardware or other thermal assemblies such as heat sinks are being assembled on top of the integrated circuit package. Moreover, the package retention frames provide a low profile retention mechanism that can be used in correspondingly low profile sockets. The package retention frame may then prevent ejection of the integrated circuit package from the socket due to spring force of the socket/package contacts during assembly or disassembly of the heat sink from the integrated circuit package. Furthermore, the package retention frame can be designed for use in an automated pick-and-place operation used to position and secure the integrated circuit to the socket on the underlying printed circuit board. For example, an automated handler or a manual operator can use features (such as tabs, clips, or latches) on the package retention frame to press down and secure the integrated circuit package in the socket. By replacing the conventional clamshell type socket actuation mechanism, the package retention frame may lead to industry-wide acceptance of land grid array sockets at least in part because the package retention frame allows the integrated circuit package to securely reside in the socket before the loading mechanism has been deployed.

The comparatively simple design of the package retention frame also significantly reduces the cost relative to the cost of a conventional socket actuation mechanism. Furthermore, since the package retention frame may be substantially encompassed by the outer boundary of the socket, the assembled package retention frame, and the integrated circuit package may consume significantly less area than the conventional socket actuation mechanisms. No retention features are used in some conventional double compression or surface mount land grid array sockets, which increases the likelihood that the socket may be damaged due to handling mishaps. The low cost, low profile, or reduced area of the package retention frame may encourage its use in double compression or surface mount land grid array sockets, which may therefore reduce contact damage from handling mishaps.

The particular embodiments disclosed above are illustrative only, as the disclosed subject matter may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

What is claimed:

1. An apparatus, comprising:
a package retention frame configured for deployment adjacent a top surface of an integrated circuit package that comprises a grid of contacts on a bottom surface of the integrated circuit package, wherein the package retention frame when deployed substantially maintains alignment of the grid of contacts with a grid of pins in a socket, and wherein an outer boundary of the package retention frame when deployed is substantially encompassed by an outer boundary of the socket.

2. The apparatus of claim 1 further comprising the socket, wherein the package retention frame substantially maintains alignment of the grid of contacts with a grid of pins in the socket.

3. The apparatus of claim 1 further comprising the socket, wherein an outer boundary of the package retention frame is substantially encompassed by an outer boundary of the socket.

4. The apparatus of claim 1, wherein the package retention frame when deployed substantially maintains alignment of the grid of contacts with the grid of pins in the absence of an additional socket actuation force.

5. The apparatus of claim 1, comprising a plurality of clips configured to attach the package retention frame to at least one of the integrated circuit package or the socket.

6. The apparatus of claim 5, wherein the plurality of clips supply sufficient force to mate the integrated circuit package and the socket when the grid of pins has less than a threshold number of pins.

7. The apparatus of claim 1, wherein the package retention frame is configured so that a socket actuation force can be applied by a heat sink to mate the integrated circuit package and the socket.

8. The apparatus of claim 7, wherein a top surface of the package retention frame when deployed is flush with a top surface of the integrated circuit package, and wherein the heat sink when deployed applies the socket actuation force to the package retention frame and the integrated circuit package.

9. The apparatus of claim 7, wherein the top surface of the package retention frame when deployed is below the top surface of the integrated circuit package, and wherein the heat sink when deployed applies the socket actuation force to the integrated circuit package and not to the package retention frame.

10. An apparatus, comprising:
a socket comprising a grid of pins;
a package retention frame, wherein an outer boundary of the package retention frame is substantially encompassed by an outer boundary of the socket.

11. The apparatus of claim 10, wherein the package retention frame substantially maintains alignment of the grid of contacts with the grid of pins in the absence of an additional socket actuation force.

12. The apparatus of claim 10, further comprising an integrated circuit package that comprises a grid of contacts on a bottom surface of the integrated circuit package, wherein the package retention frame is adjacent a top surface of the integrated circuit package, and wherein the package retention frame substantially maintains alignment of the grid of contacts with the grid of pins.

13. The apparatus of claim 12, comprising a plurality of clips configured to attach the package retention frame to at least one of the integrated circuit package or the socket.

14. The apparatus of claim 13, wherein the plurality of clips supply sufficient force to mate the integrated circuit package and the socket when the grid of pins has less than a threshold number of pins.

15. The apparatus of claim 12, comprising a heat sink that applies a socket actuation force to mate the integrated circuit package and the socket.

16. The apparatus of claim 15, wherein a top surface of the package retention frame is flush with a top surface of the integrated circuit package, and wherein the heat sink applies the socket actuation force to the package retention frame and the integrated circuit package.

17. The apparatus of claim 15, wherein the top surface of the package retention frame is below the top surface of an integrated circuit in the integrated circuit package, and wherein the heat sink applies the socket actuation force to the integrated circuit and not to the package retention frame.

18. A method, comprising:
positioning a package retention frame adjacent a top surface of an integrated circuit package that comprises a grid of contacts on a bottom surface of the integrated circuit package, wherein the package retention frame substantially maintains alignment of the grid of contacts with a grid of pins in a socket, and wherein an outer boundary of the package retention frame is substantially encompassed by an outer boundary of the socket.

19. The method of claim 18, wherein the package retention frame substantially maintains alignment of the grid of contacts with the grid of pins in the absence of an additional socket actuation force.

20. The method of claim 18, comprising clipping the package retention frame to at least one of the integrated circuit package or the socket.

21. The method of claim 20, wherein clipping the package retention frame to said at least one of the integrated circuit package or the socket comprises applying sufficient force to mate the integrated circuit package and the socket when the grid of pins has less than a threshold number of pins.

22. The method of claim 18, comprising positioning a heat sink adjacent at least one of the integrated circuit package or the socket to apply a socket actuation force to mate the package and the socket.

23. The method of claim 22, wherein positioning the package retention frame comprises positioning the package retention frame so that a top surface of the package retention frame is flush with a top surface of an integrated circuit in the integrated circuit package, and wherein positioning the heat sink comprises positioning the heat sink to apply the socket actuation force to the package retention frame and the integrated circuit so that the socket actuation force is distributed between the integrated circuit package and the integrated circuit.

24. The method of claim 22, wherein positioning the package retention frame comprises positioning the package retention frame so that the top surface of the package retention frame is below the top surface of an integrated circuit in the integrated circuit package, and wherein positioning the heat sink comprises positioning the heat sink to apply the socket actuation force to the integrated circuit and not to the package retention frame.

25. An integrated circuit package, comprising:
a grid of contacts on a bottom surface of the integrated circuit package;
an package retention frame embedded adjacent a top surface of the integrated circuit package, wherein the package retention frame when deployed substantially maintains alignment of the grid of contacts with a grid of pins in a socket, and wherein an outer boundary of the package retention frame when deployed is substantially encompassed by an outer boundary of the socket.
